(19) United States
(12) Patent Application Publication
(10) Pub. No.: US 2007/0188049 A1
(43) Pub. Date: Aug. 16, 2007

(54) Monolithic RF circuit and method of fabricating the same

(75) Inventors: In-sang Song, Seoul (KR); Sang-wook Kwon, Seongnam-si (KR); Chul-soo Kim, Hwaseong-si (KR); Yun-kwon Park, Dongducheon-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD., Suwon-si (KR)

(21) Appl. No.: 11/649,824

(22) Filed: Jan. 5, 2007

(30) Foreign Application Priority Data
Feb. 10, 2006 (KR) 10-2006-0013216

(51) Int. Cl. H01L 41/00

(52) U.S. Cl. 310/322

(57) ABSTRACT

A monolithic radio frequency (RF) circuit and a method of fabricating the monolithic RF circuit are provided. The monolithic RF circuit includes: a base substrate; a filter part including first and second support layers formed on the base substrate, a first air gap formed between the first and second support layers, a first electrode formed on the second support layer and the first air gap, a first piezoelectric layer formed on the first support layer and the first electrode, and a second electrode formed on the first piezoelectric layer; and a switch part including a third support layer adjacent to the second support layer, a second air gap formed between the second and third support layers, a first switch electrode formed on the second air gap and the third support layer, and a second piezoelectric layer formed on the first switch electrode.

### CROSS-REFERENCE TO RELATED APPLICATIONS

This application claims priority from Korean Patent Application No. 10-2006-0013216 filed Feb. 10, 2006, in the Korean Intellectual Property Office, the entire disclosure of which is incorporated herein by reference.

### BACKGROUND OF THE INVENTION

1. Field of the Invention

The present invention relates to a monolithic radio frequency (RF) circuit and a method of fabricating the same and, more particularly, to a monolithic RF circuit capable of improving productivity and a method of fabricating the same.

2. Description of the Related Art

Duplexers are wireless communication radio frequency (RF) filters as RF elements applied to wireless communication devices. The duplexers provide signals received from antennas to receivers and provide signals output from transmitters to the antennas. In other words, if a receiver and a transmitter share an antenna, such a duplexer provides a received signal only to the receiver and a transmitted signal only to the antenna.

A duplexer includes a transmitter filter and a receiver filter. The transmitter filter is a band pass filter passing only a signal in a frequency band to be transmitted. The receiver filter is a band pass filer passing only a signal in a frequency band to be received. The duplexer adjusts the frequency bands passed by the transmitter and receiver filters differently so that transmission and/or reception are performed through an antenna.

Examples of filters applied to the duplexer include a dielectric filter, a surface acoustic wave (SAW) filter, a film bulk acoustic resonator (FBAR) filter, and the like.

In particular, the FBAR filter may be integrated with other active elements on a semiconductor substrate to form the duplexer in a monolithic microwave integrated circuit (MMIC).

In this manner, the FBAR filter may be formed using a thin film process, and, thus, may have a size of one hundredth of sizes of the dielectric filter and a lumped constant (LC) filter, and also have lower insertion loss than the SAW filter. Thus, the FBAR filter is highly stable and, thus suitable for the MMIC requiring a high quality (Q) factor. Also, the FBAR filter may be fabricated to a compact size at a low fabricating cost.

The FBAR filter is formed using the thin film process and includes an upper electrode, a piezoelectric, and a lower electrode. The FBAR filter generates a resonance in a specific frequency band using a piezoelectric phenomenon and passes only a signal in a specific band using the resonance frequency.

An RF circuit of a wireless communication device includes an RF switch switching an RF signal. Examples of an RF switch applied to a high frequencies include a coaxial switch, a positive intrinsic negative (PIN) diode switch, an RF Micro Electro-Mechanical Systems (MEMS) switch, and the like. In particular, the RF MEMS switch includes an electrode part and a piezoelectric layer and is formed using a semiconductor process. Thus, the RF MEMS switch is similar to the FBAR filter in terms of a process and a structure.

However, since the piezoelectric layer of the RF MEMS switch is different from the piezoelectric of the FBAR filter, the RF MEMS switch and the FBAR filter are formed on different substrates. Thus, a process of forming the RF MEMS switch and a process of forming the FBAR filter are separately performed. As a result, production of the RF circuit may be inefficient.

### SUMMARY OF THE INVENTION

Exemplary embodiments of the present invention may overcome the above disadvantages and other disadvantages not described above. Also, the present invention is not required to overcome the disadvantages described above, and an exemplary embodiment of the present invention may not overcome any of the problems described above.

The present invention provides a monolithic radio frequency (RF) circuit and a method of fabricating the monolithic RF circuit.

According to an aspect of the present invention, a monolithic radio frequency (RF) circuit includes a base substrate; a filter part including a first support layer and a second support layer formed on the base substrate, a first air gap formed between the first support layer and the second support layers, a first electrode formed on the second support layer and the first air gap, a first piezoelectric layer formed on the first support layer and the first electrode, and a second electrode formed on the first piezoelectric layer; and a switch part including a third support layer formed on the base substrate to be adjacent to the second support layer, a second air gap formed between the second support layer and the third support layer, a first switch electrode formed on the second air gap and the third support layer, and a second piezoelectric layer formed on the first switch electrode, wherein the switch part switches an RF signal input from an external source.

The first piezoelectric layer and the second piezoelectric layer may be formed of the same material.

A portions of the first switch electrode may be formed on the second support layer and a portion of the second piezoelectric layer may be formed on the portion of the first switch electrode.

The switch part may further include a second switch electrode formed on the second piezoelectric layer. A portion of the second switch electrode may be formed above the second support layer.

According to another aspect of the present invention, a monolithic RF circuit includes a base substrate; a filter part including a first support layer and a second support layer formed on the base substrate, a first air gap formed between the first support layer and the second support layer, a first electrode formed on the second support layer and the first air gap, a first piezoelectric layer formed on the first support layer and the first electrode, and a second electrode formed on the first piezoelectric layer; and a switch part including a third support layer formed on the base substrate to be adjacent to the second support layer, a second air gap formed between the second support layer and third support layer, a second piezoelectric layer formed on the second air gap and the third support layer, and a switch electrode formed on the second piezoelectric layer, wherein the switch part switches an RF signal input from an external source.

The first piezoelectric layer and the second piezoelectric layer may be formed of the same material.

A portions of the second piezoelectric layer may be formed on the second support layer and a portion of the switch electrode is formed on the portion of the second piezoelectric layer.

According to another aspect of the present invention, a method of fabricating a monolithic RF circuit includes forming a first metal layer on a base substrate; patterning the first metal layer to form a first support layer, a second support layer, and a third support layer; forming a first sacrificial layer between the first support layer and the second support layer and a second sacrificial layer between the second support layer and third support layer; forming a first electrode on the second support layer and the first sacrificial layer and a first switch electrode on the third support layer and the second sacrificial layer; depositing a piezoelectric material on the base substrate on which the first electrode and the first switch electrode are formed; patterning the piezoelectric material to form a first piezoelectric layer on the first support layer and the first electrode and forming a second piezoelectric layer on the first switch electrode; forming a second electrode on the first piezoelectric layer; and removing the first sacrificial layer to form a first air gap and removing the second sacrificial layer to form a second air gap.

The formation of the first electrode on the second support layer and the first sacrificial layer and the first switch electrode on the third support layer and the second sacrificial layer may include: depositing a second metal layer on the base substrate on which the first support layer and the second support layers are formed; and patterning the second metal layer to form the first electrode and the first switch electrode.

The formation of the second electrode and the on the first piezoelectric layer may include: depositing a third metal layer on the base substrate on which the first piezoelectric layer and the second piezoelectric layer are formed; and patterning the third metal layer to form the second electrode.

The formation of the second electrode on the first piezoelectric layer further may include: patterning the third metal layer to form a second switch electrode on the second piezoelectric layer.

According to another aspect of the present invention, a method of fabricating a monolithic RF circuit includes forming a first metal layer on a base substrate; patterning the first metal layer to form a first support layer, a second support layer, and a third support layer; forming a first sacrificial layer between the first support layer and the second support layer and a second sacrificial layer between the second support layer and third support layer; forming a first electrode on the second support layer and the first sacrificial layer; depositing a piezoelectric material on the base substrate on which the first electrode is formed; patterning the piezoelectric material to form a first piezoelectric layer on the third support layer and the second sacrificial layer; forming a second electrode on the first piezoelectric layer and a switch electrode on the second piezoelectric layer; and removing the first sacrificial layer to form a first air gap and removing the second sacrificial layer to form a second air gap.

The formation of the second electrode on the first piezoelectric layer and the switch electrode on the piezoelectric layer may include: depositing a second metal layer on the base substrate on which the first piezoelectric layer and the second piezoelectric layer are formed; and patterning the second metal layer to form the second electrode and the switch electrode.

### BRIEF DESCRIPTION OF THE DRAWINGS

The above and other aspects of the present invention will be more apparent by describing certain exemplary embodiments of the present invention with reference to the accompanying drawings, in which:

FIG. 1 is a cross-sectional view of a monolithic radio frequency (RF) circuit according to an exemplary embodiment of the present invention;

FIGS. 2A through 2H are cross-sectional views illustrating a method of fabricating the monolithic RF circuit shown in FIG. 1;

FIG. 3 is a cross-sectional view of a monolithic RF circuit according to another exemplary embodiment of the present invention;

FIG. 4 is a cross-sectional view of a monolithic RF circuit according to another exemplary embodiment of the present invention; and

FIGS. 5A through 5D are cross-sectional views illustrating a method of fabricating the monolithic RF circuit shown in FIG. 4.

### DETAILED DESCRIPTION OF EXEMPLARY EMBODIMENTS

Reference will now be made in detail to exemplary embodiments of the present invention, examples of which are illustrated in the accompanying drawings, wherein like reference numerals refer to the like elements throughout. The exemplary embodiments are described below in order to explain various aspects of the present invention by referring to the figures.

The matters defined in the description such as the detailed construction and elements are provided to assist in a comprehensive understanding of the invention. Thus, it would be apparent to one skilled in the art that the present invention can be practiced out without those defined matters. Also, well-known functions or constructions are not described in detail since they would obscure the invention with unnecessary detail.

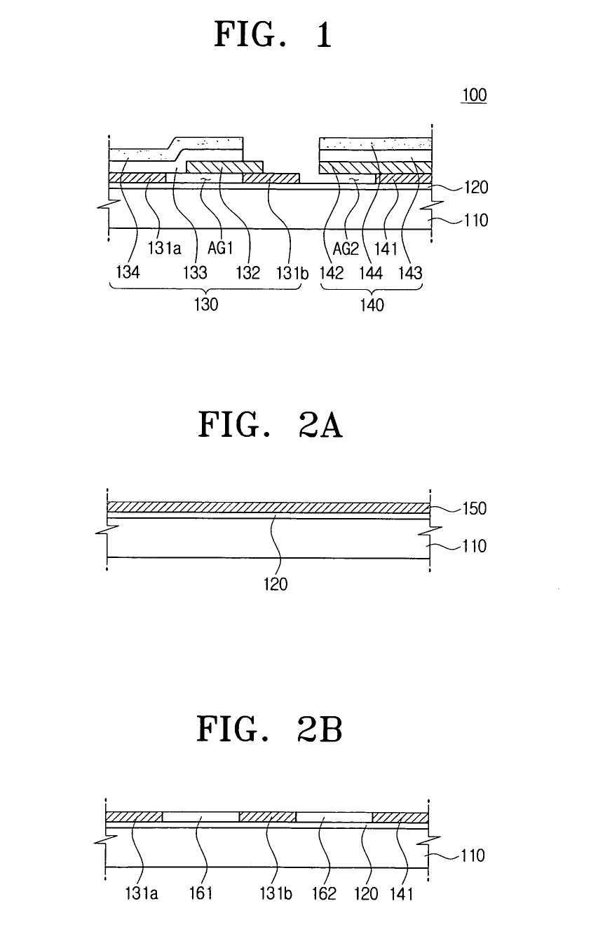

FIG. 1 is a cross-sectional view of a monolithic radio frequency (RF) circuit according to an exemplary embodiment of the present invention. Referring to FIG. 1, a monolithic RF circuit 100 according to the exemplary embodiment of the present invention includes a base substrate 110, an insulating layer 120, a filter part 130, and a switch part 140.

In detail, the base substrate 110 is a semiconductor insulating substrate and may be formed of silicon wafer.

The insulating layer 120 is formed of an insulating material such as a silicon dioxide (SiO₂) on the base substrate 110.

The filter part 130 is formed on an upper surface of the insulating layer 120 and passes only a signal in a specific frequency band. The filter part 130 includes first and second support layers 131a and 131b, a first electrode 132, a first piezoelectric layer 133, and a second electrode 134.

The first and second support layers 131a and 131b are formed of a metallic material on the insulating layer 120. A first air gap AG1 is formed between the first and second support layers 131a and 131b.

The first electrode 132 is formed on the second support layer 131b and the first air gap AG1. The first electrode 132 is formed of a conductive metallic material, e.g., copper (Cu), aluminum (Al), tungsten (W), aurum (Au), platinum (Pt), nickel (Ni), titanium (Ti), chrome (Cr), palladium (Pd), molybdenum (Mo), or the like. Here, the first electrode 132 covers a portion of the second support layer 131b and a portion of the first air gap AG1.

The first piezoelectric layer 133 is formed on upper surfaces of the first electrode 132 and the first support layer 131a. The first piezoelectric layer 133 covers a portion of the first electrode 132 and the upper surface of the first support layer 131a. The first piezoelectric layer 133 is also formed on a portion of the first air gap AG1 exposed between the first support layer 131a and the first electrode 132. The first piezoelectric layer 133 is formed of a piezoelectric film generating a piezoelectric effect in which electrical energy is converted into mechanical energy of elastic form.

The second electrode 134 is formed on an upper surface of the first piezoelectric layer 133. The second electrode 134 is formed of a conductive metallic material, e.g., copper (Cu), aluminum (Al), tungsten (W), aurum (Au), platinum (Pt), nickel (Ni), titanium (Ti), chrome (Cr), palladium (Pd), molybdenum (Mo), or the like.

As described above, in the filter part 130, the first piezoelectric layer 133 is formed between the first and second electrodes 132 and 134. If a power source is connected to the first and second electrodes 132 and 134, the first piezoelectric layer 133 generates the piezoelectric effect, which generates a resonance phenomenon. Here, the filter part 130 passes only a signal in a frequency band equal to a resonance frequency.

The switch part 140 is formed beside the filter part 130 and switches an RF signal input from an external source. The switch part 140 includes a third support layer 141, a first switch electrode 142, and a second piezoelectric layer 143.

The third support layer 141 is positioned adjacent to the second support layer 131b and formed of a metallic material. A second air gap AG2 is formed between the second support layer 131b and the third support layer 141. The second air gap AG2 also separates the third support layer 141 from the second support layer 131b.

The first switch electrode 142 is formed on the third support layer 141 and the second air gap AG2. The first switch electrode 142 exposes a portion of the second air gap AG2 to be insulated from the filter part 130. The first switch electrode 142 is formed of a conductive metallic material, e.g., copper (Cu), aluminum (Al), tungsten (W), aurum (Au), platinum (Pt), nickel (Ni), titanium (Ti), chrome (Cr), palladium (Pd), molybdenum (Mo), or the like.

The second piezoelectric layer 143 is formed on an upper surface of the first switch electrode 142. The second piezoelectric layer 143 is formed of the same material as a material of which the first piezoelectric layer 133 is to be formed. Here, the second piezoelectric layer 143 is formed along with the first piezoelectric layer 133 in a process of forming the first piezoelectric layer 133.

The switch part 140 further includes a second switch electrode 144 formed on the second piezoelectric layer 143. The second switch electrode 144 is formed of a conductive metallic material, e.g., copper (Cu), aluminum (Al), tungsten (W), aurum (Au), platinum (Pt), nickel (Ni), titanium (Ti), chrome (Cr), palladium (Pd), molybdenum (Mo), or the like.

The second piezoelectric layer 143 is interposed between the first and second switch electrodes 142 and 144.

As described above, in the monolithic RF circuit 100, the filter part 130 and the switch part 140 are formed in company with each other on the base substrate 110 to form a duplexer and the switch part 140 into an MMIC.

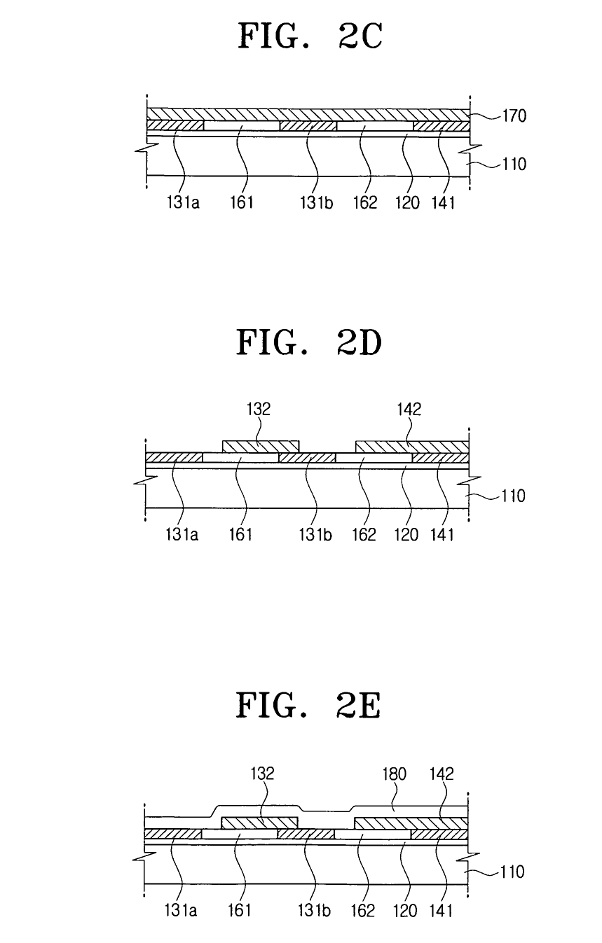

FIGS. 2A through 2H are cross-sectional views illustrating a method of fabricating the monolithic RF circuit 100 illustrated in FIG. 1. Referring to FIGS. 2A and 2B, the insulating layer 120 is formed on the base substrate 110 using an RF magnetron sputtering method or an evaporation method. A first metal layer 150 is formed on the insulating layer 120.

As shown in FIG. 2B, the first metal layer 150 is patterned to form the first, second, and third support layers 131a, 131b, and 141. First and second sacrificial layers 161 and 162 are formed on the insulating layer 120 on which the first, second, and third support layers 131a, 131b, and 141 are formed. Here, the first sacrificial layer 161 is positioned between the first and second support layers 131a and 131b, and the second sacrificial layer 162 is positioned between the second and third support layers 131b and 141.

Referring to FIGS. 2C and 2D, a second metal layer 170 is deposited on the first, second, and third support layers 131a, 131 b, and 141 and the first and second sacrificial layers 161 and 162.

As shown in FIG. 2D, the second metal layer 170 is patterned to form the first and second electrodes 132 and 142.

Referring to FIGS. 2E and 2F, a piezoelectric film 180 is deposited on the base substrate 110 on which the first and second electrodes 132 and 142 are formed.

As shown in FIG. 2F, the piezoelectric film 180 is patterned to form the first piezoelectric layer 133 on the first support layer 131a and the first electrode 132 and form the second piezoelectric layer 143 on the upper surface of the first switch electrode 142.

Referring to FIGS. 2G and 2H, a third metal layer 190 is deposited on the base substrate 110 on which the first and second piezoelectric layers 133 and 143 are formed.

As shown in FIG. 2H, the third metal layer 190 is patterned to form the second electrode 134 on the first piezoelectric layer 133 and form the second switch electrode 144 on the second piezoelectric layer 143

The first and second sacrificial layers 161 and 162 are removed to form the first and second air gaps AG1 and AG2 shown in FIG. 1, respectively. As a result, the filter part 130 and the switch part 140 are completed.

As described above, in the monolithic RF circuit 100, the filter part 130 and the switch part 140 are formed on the base substrate 110. Here, the switching unit 140 is formed along with the filter part 130 in a process of the forming the filter part 130. Thus, the filter part 130 and the switch part 140 may be integrated into the MMIC. As a result, a process time can be reduced to improve productivity.

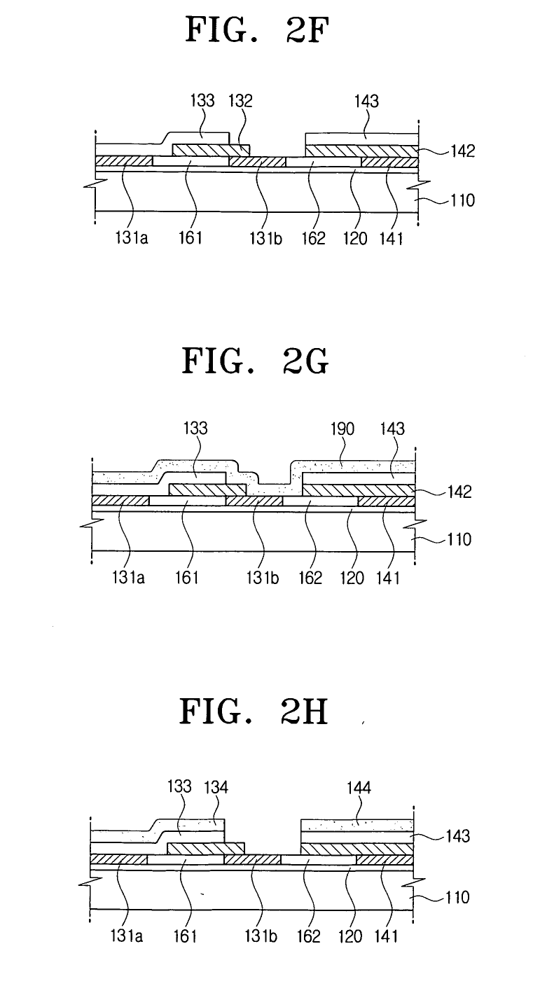

FIG. 3 is a cross-sectional view of a monolithic RF circuit according to another exemplary embodiment of the present invention. Referring to FIG. 3, a monolithic RF circuit 200 according to another exemplary embodiment of the present invention has the same structure as the monolithic RF circuit 100 illustrated in FIG. 1 with the exception of switch part 210. Thus, the same reference numerals of the monolithic RF circuit 200 as those of the monolithic RF circuit 100 denote like elements, and thus their detailed descriptions will be omitted.

The monolithic RF circuit 200 includes a base substrate 110, an insulating layer 120, a filter part 130, and the switch part 210.

In detail, the insulating layer 120 is formed on an upper surface of the base substrate 110, and the filter part 130 and the switch part 210 are formed on the insulating layer 120.

The filter part 130 is formed on an upper surface of the insulating layer 120 and passes only a signal in a specific frequency band. The filter part 130 includes first and second support layers 131a and 131b, a first electrode 132, a first piezoelectric layer 133, and a second electrode 134.

The switch part 210 switches an RF signal input from an external source. The switch part 210 includes a third support layer 141, a first switch electrode 211, and a second piezoelectric layer 212.

The third support layer 141 is formed on the upper surface of the insulating layer 120 using the same material as a material of which the first and second support layers 131a and 131b are to be formed. A second air gap AG2 is formed between the second support layer 131b and the third support layer 141.

The first switch electrode 211 is formed on an upper surface of the third support layer 141 and on the second air gap AG2. In particular, a portion of the first switch electrode 211 is formed on an upper surface of the support layer 131b, and the first switch electrode 211 is spaced apart from the first electrode 132. The first switch electrode 211 is formed of a conductive metallic material, e.g., copper (Cu), aluminum (Al), tungsten (W), aurum (Au), platinum (Pt), nickel (Ni), titanium (Ti), chrome (Cr), palladium (Pd), molybdenum (Mo), or the like.

The second piezoelectric layer 212 is formed on an upper surface of the first switch electrode 211, and a portion of the second piezoelectric layer 212 is positioned in an area in which the second support layer 131b is formed. The second piezoelectric layer 212 is formed of the same material as a material of which the first piezoelectric layer 133 is to be formed, along with the first piezoelectric layer 133 in a process of forming the first piezoelectric layer 133.

The switch part 210 further includes a second switch electrode 213 formed on the second piezoelectric layer 212.

A portion of the second switch electrode 213 is positioned in an area in which the second support layer 131b is formed, and the second switch electrode 213 is formed of a conductive metallic material, e.g., copper (Cu), aluminum (Al), tungsten (W), aurum (Au), platinum (Pt), nickel (Ni), titanium (Ti), chrome (Cr), palladium (Pd), molybdenum (Mo), or the like.

Here, the process of forming the monolithic RF circuit 200 is the same as the process of forming the monolithic RF circuit 100 illustrated in FIGS. 2A through 2H, and thus its description will be omitted.

As described above, in the monolithic RF circuit 200, the filter part 130 and the switch part 210 are formed on the base substrate 110 to form a duplexer and the switch part 210 into an MMIC. Also, a fabricating process time can be reduced to improve productivity.

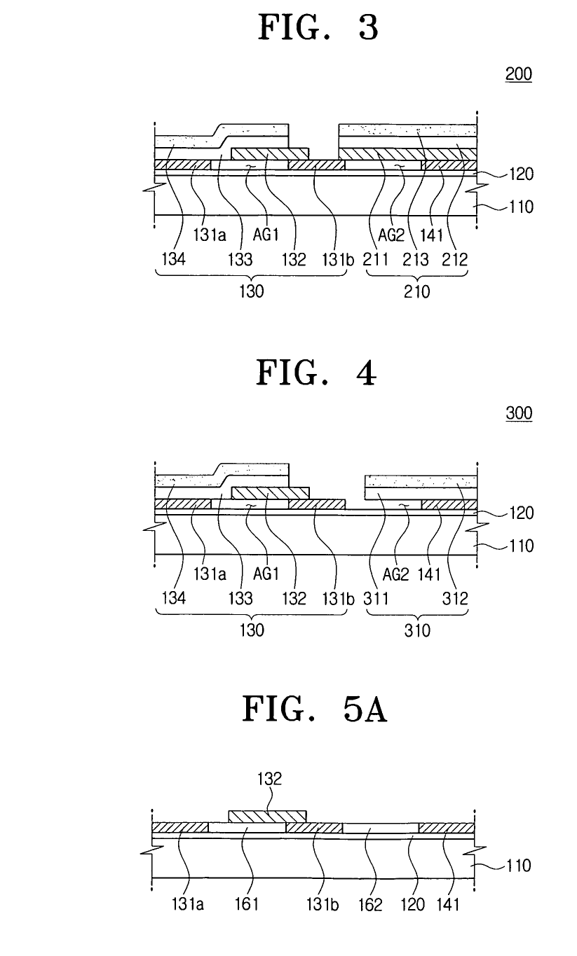

FIG. 4 is a cross-sectional view of a monolithic RF circuit according to another exemplary embodiment of the present invention. Referring to FIG. 4, a monolithic RF circuit 300 according to another exemplary embodiment of the present invention has the same structure as the monolithic RF circuit 100 illustrated in FIG. 1 except a switch part 310. Thus, the same reference numerals of the monolithic RF circuit 300 as those of the monolithic RF circuit 100 of FIG. 1 denote like reference and, thus, their detailed descriptions will be omitted.

The monolithic RF circuit 300 includes a base substrate 110, an insulating layer 120, a filter part 130, and the switch part 310.

In detail, the insulating layer 120 is formed on an upper surface of the base substrate 110, and the filter part 130 and the switch part 310 are formed on the insulating layer 120.

The filter part 130 is formed on an upper surface of the insulating layer 120 and passes only a signal in a specific frequency band. The filter part 130 includes first and second support layers 131a and 131b, a first electrode 132, a first piezoelectric layer 133, and a second electrode 134.

The switch part 310 switches an RF signal input from an external source. The switch part 310 includes a third support layer 141, a second piezoelectric layer 311, and a switch electrode 312.

The third support layer 141 is formed on the upper surface of the insulating layer 120 using the same material as a material of which the first and second support layers 131a and 131b are to be formed. A second air gap AG2 is formed between the second support layer 131b and the third support layer 141.

The second piezoelectric layer 311 is formed on an upper surface of the third support layer 141 and on the second air gap AG2. The second piezoelectric layer 311 is formed of the same material as a material of which the first piezoelectric layer 133 is to be formed, along with the first piezoelectric layer 133 in a process of forming the first piezoelectric layer 133.

In the exemplary embodiment of the present invention, a portion of the second air gap AG2 is exposed between the first electrode 132 and the second piezoelectric layer 311. However, the second piezoelectric layer 311 may extend to the second support layer 131b. In this case, the second air gap AG2 is not exposed.

The switch electrode 312 is formed on an upper surface of the second piezoelectric layer 311 using a conductive metallic material, e.g., copper (Cu), aluminum (Al), tungsten (W), aurum (Au), platinum (Pt), nickel (Ni), titanium (Ti), chrome (Cr), palladium (Pd), molybdenum (Mo), or the like.

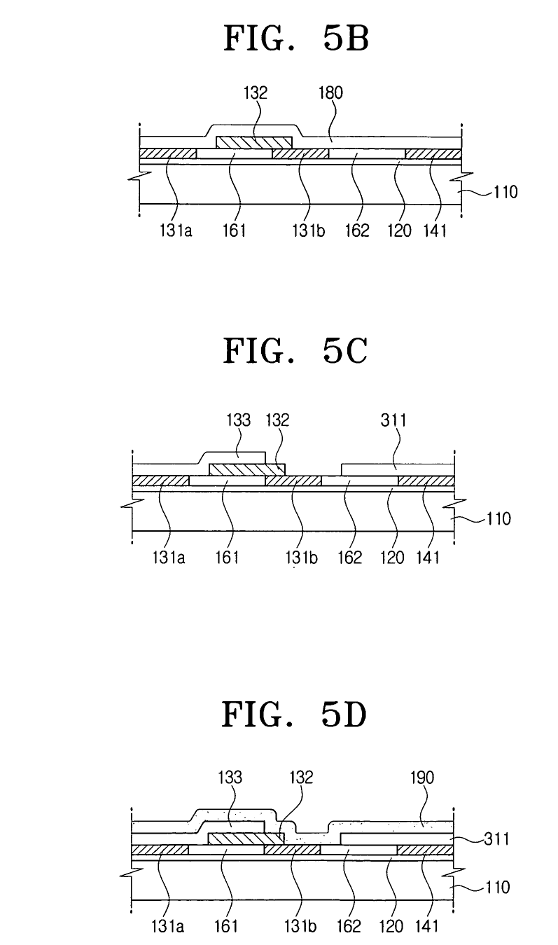

FIGS. 5A through 5D are cross-sectional views illustrating a method of fabricating the monolithic RF circuit 300 illustrated in FIG. 4.

Referring to FIG. 5A, the insulating layer 120 is formed on the base substrate 110, and the first, second, and third support layers 131a, 131b, and 141 and first and second sacrificial layers 161 and 162 are formed on the upper surface of the insulating layer 120. Here, the process of forming the insulating layer 120, the first, second, and third support layers 131a, 131 b, and 141, and the first and second sacrificial layers 161 and 162 is as described with reference to FIGS. 2A and 2B. Thus, the detailed description of the process will be omitted.

A second metal layer 170 (refer to FIG. 2C) is formed on the base substrate 110 and then patterned to form the first electrode 132.

Referring to FIGS. 5B and 5C, a piezoelectric film 180 is deposited on the base substrate 110 on which the first electrode 132 is formed.

As shown in FIG. 5C, the piezoelectric film 180 is patterned to form the first piezoelectric layer 133 on the first support layer 131a and the fist electrode 132 and form the second piezoelectric layer 311 on upper surfaces of the third support layer 141 and the second sacrificial layer 162.

Referring to FIGS. 4 and 5D, a third metal layer 190 is deposited on the base substrate 110 on which the first and second piezoelectric layers 133 and 143 are formed.

The third metal layer 190 is patterned to form the second electrode 134 on the first piezoelectric layer 133 and form the switch electrode 312 on the second piezoelectric layer 311 as shown in FIG. 4.

The first and second sacrificial layers 161 and 162 are removed to form the first and second air gaps AG1 and AG2 (refer to FIG. 1). As a result, the filter part 130 and the switch part 310 are completed.

As described above, in the monolithic RF circuit 300, the filter part 130 and the switch part 310 are formed on the base substrate 110. Here, the switch part 310 is formed along with the filter part 130 in the process of forming the filter part 130. Thus, the filter part 130 and the switch part 310 may be formed into an MMIC. Also, a process time may be reduced to improve productivity.

As described above, in a monolithic RF circuit according to exemplary embodiments of the present invention, a filter part and a switch part can be formed on a base substrate. In particular, the switch part can be formed along with the filter part in a process of forming the filter part. Also, the switch part can be formed using the same process as that of forming the filter part. As a result, the filter part and the switch part can be formed into an MMIC. Also, a process time may be reduced to improve productivity.

The foregoing embodiments are merely exemplary and are not to be construed as limiting the present invention. The present teaching can be readily applied to other types of apparatuses. Also, the description of the exemplary embodiments of the present invention is intended to be illustrative, and not to limit the scope of the claims, and many alternatives, modifications, and variations will be apparent to those skilled in the art.

What is claimed is:

1. A monolithic RF (radio frequency) circuit comprising:
a base substrate;
a filter part comprising a first support layer and a second support layer formed on the base substrate, a first air gap formed between the first support layer and the second support layer, a first electrode formed on the second support layer and the first air gap, a first piezoelectric layer formed on the first support layer and the first electrode, and a second electrode formed on the first piezoelectric layer; and
a switch part comprising a third support layer formed on the base substrate to be adjacent to the second support layer, a second air gap formed between the second support layer and the third support layer, a first switch electrode formed on the second air gap and the third support layer, and a second piezoelectric layer formed on the first switch electrode,
wherein the switch part switches an RF signal input from an external source.

2. The monolithic RF circuit as claimed in claim 1, wherein the first piezoelectric layer and the second piezoelectric layer are formed of the same material.

3. The monolithic RF circuit as claimed in claim 1, wherein a portion of the first switch electrode is formed on the second support layer and a portion of the second piezoelectric layer is formed on the portion of the first switch electrode.

4. The monolithic RF circuit as claimed in claim 1, wherein the switch part further comprises a second switch electrode formed on the second piezoelectric layer.

5. The monolithic RF circuit as claimed in claim 4, wherein a portion of the second switch electrode is formed above the second support layer.

6. A monolithic RF circuit comprising:
a base substrate;
a filter part comprising a first support layer and a second support layer formed on the base substrate, a first air gap formed between the first support layer and the second support layer, a first electrode formed on the second support layer and the first air gap, a first piezoelectric layer formed on the first support layer and the first electrode, and a second electrode formed on the first piezoelectric layer; and
a switch part comprising a third support layer formed on the base substrate to be adjacent to the second support layer, a second air gap formed between the second support layer and the third support layer, a second piezoelectric layer formed on the second air gap and the third support layer, and a switch electrode formed on the second piezoelectric layer,
wherein the switch part switches an RF signal input from an external source.

7. The monolithic RF circuit as claimed in claim 6, wherein the first piezoelectric layer and the second piezoelectric layer are formed of the same material.

8. The monolithic RF circuit as claimed in claim 6, wherein a portion of the second piezoelectric layer is formed on the second support layer and a portion of the switch electrode is formed on the portion of the second piezoelectric layer.

9. A method of fabricating a monolithic RF circuit, comprising:
forming a first metal layer on a base substrate;
patterning the first metal layer to form a first support layer, a second support layer, and a third support layer;
forming a first sacrificial layer between the first support layer and the second support layer and a second sacrificial layer between the second support layer and the third support layer;
forming a first electrode on the second support layer and the first sacrificial layer and a first switch electrode on the third support layer and the second sacrificial layer;
depositing a piezoelectric material on the base substrate on which the first electrode and the first switch electrode are formed;
patterning the piezoelectric material to form a first piezoelectric layer on the first support layer and the first electrode and forming a second piezoelectric layer on the first switch electrode;
forming a second electrode on the first piezoelectric layer; and
removing the first sacrificial layer to form a first air gap and removing the second sacrificial layer to form a second air gap.

10. The method as claimed in claim 9, wherein the formation of the first electrode on the second support layer and the first sacrificial layer and the first switch electrode on the third support layer and the second sacrificial layer comprises:
depositing a second metal layer on the base substrate on which the first support layer and the second support layer are formed; and
patterning the second metal layer to form the first electrode and the first switch electrode.

11. The method as claimed in claim 9, wherein the formation of the second electrode on the first piezoelectric layer comprises:
depositing a third metal layer on the base substrate on which the first piezoelectric layer and the second piezoelectric layer are formed; and
patterning the third metal layer to form the second electrode.

12. The method as claimed in claim 11, wherein the formation of the second electrode on the first piezoelectric layer further comprises:
patterning the third metal layer to form a second switch electrode on the second piezoelectric layer.

13. A method of fabricating a monolithic RF circuit, comprising:
forming a first metal layer on a base substrate;
patterning the first metal layer to form a first support layer, a second support layer, and a third support layer;
forming a first sacrificial layer between the first support layer and the second support layer and a second sacrificial layer between the second support layer and third support layer;
forming a first electrode on the second support layer and the first sacrificial layer;
depositing a piezoelectric material on the base substrate on which the first electrode is formed;
patterning the piezoelectric material to form a first piezoelectric layer on the first electrode and the first sacrificial layer and a second piezoelectric layer on the third support layer and the second sacrificial layer;
forming a second electrode on the first piezoelectric layer and a switch electrode on the second piezoelectric layer; and
removing the first sacrificial layer to form a first air gap and removing the second sacrificial layer to form a second air gap.

14. The method as claimed in claim 13, wherein the formation of the second electrode on the first piezoelectric layer and the switch electrode on the second piezoelectric layer comprises:
depositing a second metal layer on the base substrate on which the first piezoelectric layer and second piezoelectric layer are formed; and
patterning the second metal layer to form the second electrode and the switch electrode.
